(19) United States
(12) Patent Application Publication
(10) Pub. No.: US 2026/0157012 A1
(43) Pub. Date: Jun. 4, 2026

(54) BACKLIGHT MODULES AND DISPLAY DEVICES

(71) Applicant: Wuhan China Star Optoelectronics Technology Co., Ltd., Wuhan, Hubei (CN)

(72) Inventors: Nongyun Sun, Wuhan, Hubei (CN); Zheng ZHOU, Wuhan, Hubei (CN); Suimang SONG, Wuhan, Hubei (CN)

(21) Appl. No.: 18/253,783

(22) PCT Filed: Mar. 24, 2023
(86) PCT No.: PCT/CN2023/083899

§ 371 Date: May 21, 2023

(30) Foreign Application Priority Data
Feb. 16, 2023 (CN) 202310137233.5

(51) Int. Cl. H10H 29/85; G02F 1/1335; G02F 1/13357; H10H 20/857

(52) U.S. Cl. CPC H10H 29/857; G02F 1/133603; G02F 1/133612; H10H 20/857

(57) ABSTRACT

Backlight modules and display devices are provided. In which, power supply traces are each directly connected with a power terminal, and connection traces are each non-directly connected with the power terminal. Each first pin is directly connected with the power supply trace, and each second pin is directly connected with the connection trace. Mounting parts include first mounting parts, each of which including one first pin and at least two second pins adjacent to the first pin, and/or, second mounting parts, each of which including one second pin and at least two first pins adjacent to the second pin.

### TECHNICAL FIELD

The present disclosure relates to the field of display technologies, and in particular, to backlight modules and display devices.

### BACKGROUND

Mini light emitting diode (mini-LEDs for short) displays have characteristic of self-emission display and have advantages of all-solid-state, long life, high brightness, low power dissipation, small size, ultra-high resolution, and applicability in extreme environments such as high temperature or radiation. Compared with organic light-emitting diode display technology characterized by self-emission display, mini-LED display technologies not only have higher efficiency, longer service life, relatively stable material which is not susceptible to environmental influences, but also can avoid the phenomenon of residual shadow. Because indicators, such as brightness, contrast, life, viewing angle and resolution, of a display device with a mini-LED backlight are better than those of a traditional liquid crystal display device and those of a traditional OLED display device. The display device with the mini-LED backlight is regarded as the next generation of display technology, and is actively developed.

At present, LED chips in a mini-LED backlight module are generally mounted on a circuit board by a surface mounted technology (SMT for short). It is necessary to form pads on the circuit board in advance, so that the LED chips can be welded on the pads later. However, since an arrangement (such as arrangement directions of the pads, etc.) of the pads on the circuit board has been determined during an installation of the LED chips, a new circuit board is necessary to be prepared when a new arrangement mode of the LED chips is needed, which leads to extension of the process and increases the costs.

### SUMMARY OF THE INVENTION

### Technical Problems

Backlight modules and display devices according to embodiments of the present disclosure are provided, in which, various arrangement modes of pins are provided on a same substrate, so that light-emitting elements mounted on the substrate can also have various arrangement modes, thereby improving compatibility and applicability of the backlight modules.

### Technical Solutions

An embodiment of the present disclosure provides a backlight module, including:
a substrate;
a power terminal and a plurality of power supply traces, disposed on the substrate, herein, each of the power supply traces is directly connected with the power terminal;
a plurality of connection traces, disposed on the substrate, herein, each of the connection traces is non-directly connected with the power terminal; and
a plurality of mounting parts, disposed on the substrate, the plurality of mounting parts including a plurality of first pins and a plurality of second pins, each of the first pins being directly connected with one of the power supply traces, and each of the second pins being directly connected with one of the connection traces, herein, the plurality of mounting parts include first mounting parts, each of which including one first pin of the first pins and at least two second pins of the second pins adjacent to the first pin, and/or, second mounting parts, each of which including one second pin of the second pins and at least two first pins of the first pins adjacent to the second pin.

According to an embodiment of the present disclosure, the backlight module further includes light-emitting elements each connected with one of the mounting parts; and the light-emitting elements include first light-emitting elements, each of which connected with the first pin and an adjacent one of the second pins in a same one of the first mounting parts, and/or, second light-emitting element, each of which connected with the second pin and an adjacent one of the first pins in a same one of the second mounting parts.

According to an embodiment of the present disclosure, in each of the first mounting parts, the first pin is adjacent to one of the second pins along a first direction and is adjacent to the other one of the second pins along a second direction;
and/or, in each of the second mounting parts, the second pin is adjacent to one of the first pins along the first direction and is adjacent to the other one of the first pins along the second direction; and
herein, each of the first pins is spaced apart from adjacent ones of the second pins in a same one of the mounting parts.

According to an embodiment of the present disclosure, the power terminal includes a first positive port and a first negative port disposed on the substrate; and
herein, the plurality of first pins include first positive pins each connected with the first positive port through one of the power supply traces and first negative pins each connected with the first negative port through one of the power supply traces; and the plurality of second pins include second negative pins each adjacent to one of the first positive pins along the first direction or the second direction and second positive pins each adjacent to one of the first negative pins along the first direction or the second direction.

According to an embodiment of the present disclosure, the backlight module further includes one or more first circuits connected with the first positive port and the first negative port, and each of the first circuits includes two mounting parts of the mounting parts arranged along the first direction;
herein, a first one of the two mounting parts includes one first positive pin of the first positive pins connected with the first positive port through one of the power supply traces, one second negative pin of the second negative pins disposed on a side of the first positive pin adjacent to another one of the two mounting parts along the first direction, and another second negative pin of the second negative pins adjacent to the first positive pin along the second direction; and
a second one of the two mounting parts includes one first negative pin of the first negative pins connected with the first negative port through one of the power supply traces, one second positive pin of the second positive pins disposed on a side of the first negative pin adjacent to another one of the two mounting parts along the first direction, and another second positive pin of the second positive pins adjacent to the first negative pin along the second direction.

According to an embodiment of the present disclosure, in each of the first circuits, the second negative pins in the first one of the two mounting parts are each connected with one of the second positive pins in the second one of the two mounting parts through one of the connection trances.

According to an embodiment of the present disclosure, the backlight module further includes one or more second circuits connected with the first positive port and the first negative port, and each of the second circuits includes two mounting parts of the mounting parts arranged along the first direction;
herein, a first one of the two mounting parts includes one first positive pin of the first positive pins connected with the first positive port through one of the power supply traces, one second negative pin of the second negative pins disposed on a side of the first positive pin adjacent to another one of the two mounting parts along the first direction, and another first positive pin of the first positive pins adjacent to the second negative pin along the second direction; and
a second one of the two mounting parts includes one first negative pin of the first negative pins connected with the first negative port through one of the power supply traces, one second positive pin of the second positive pins disposed on a side of the first negative pin adjacent to another one of the two mounting parts along the first direction, and another first negative pin of the first negative pins adjacent to the second positive pin along the second direction.

According to an embodiment of the present disclosure, in each of the second circuits, the second negative pin in the first one of the two mounting parts is connected with the second positive pin in the second one of the two mounting parts through one of the connection trances.

According to an embodiment of the present disclosure, the power terminal further includes a second positive port and a second negative port, and each of the second circuits is further connected with the second positive port and the second negative port; and
herein, in each of the second circuits, the first positive pin adjacent to the second negative pin along the second direction is connected with the second positive port through one of the power supply traces, and the first negative pin adjacent to the second positive pin along the second direction is connected with the second negative port through one of the power supply traces.

According to an embodiment of the present disclosure, for one light-emitting element of the light-emitting elements and one mounting part of the mounting parts connected with each other, the light-emitting element is connected with one first positive pin of the first positive pins and one of the second negative pins adjacent to the first positive pin along the first direction or the second direction;
and/or, the light-emitting element is connected with one second positive pin of the second positive pins and one of the first negative pins adjacent to the second positive pin along the first direction or the second direction.

According to an embodiment of the present disclosure, in each of the first mounting parts, a first distance is defined between the first pin and any one of the at least two second pins adjacent to the first pin; and
in each of the second mounting parts, a second distance is defined between the second pin and any one of the at least two first pins adjacent to the second pin, and the first distance is equal to the second distance.

According to an embodiment of the present disclosure, each of the light-emitting elements includes a positive electrode and a negative electrode; and for one light-emitting element of the light-emitting elements and one mounting part of the mounting parts connected with each other, the positive electrode is connected with one of the first pin and the second pin, and the negative electrode is connected with the other one of the first pin and the second pin; and
herein, a distance between the positive electrode and the negative electrode is equal to the first distance or the second distance.

In view of above, an embodiment of the present disclosure further provides a display device. The display device includes a display panel and a backlight module, and the display panel disposed on a light output side of the backlight module; and
the backlight module includes:
a substrate;
a power terminal and a plurality of power supply traces, disposed on the substrate, herein, each of the power supply traces is directly connected with the power terminal;
a plurality of connection traces, disposed on the substrate, herein, each of the connection traces is non-directly connected with the power terminal; and
a plurality of mounting parts, disposed on the substrate, the plurality of mounting parts including a plurality of first pins and a plurality of second pins, each of the first pins being directly connected with one of the power supply traces, and each of the second pins being directly connected with one of the connection traces, herein, the plurality of mounting parts include first mounting parts, each of which including one first pin of the first pins and at least two second pins of the second pins adjacent to the first pin, and/or, second mounting parts, each of which including one second pin of the second pins and at least two first pins of the first pins adjacent to the second pin.

According to an embodiment of the present disclosure, the backlight module further includes light-emitting elements each connected with one of the mounting parts; and the light-emitting elements include first light-emitting elements, each of which connected with the first pin and an adjacent one of the second pins in a same one of the first mounting parts, and/or, second light-emitting element, each of which connected with the second pin and an adjacent one of the first pins in a same one of the second mounting parts.

According to an embodiment of the present disclosure, in each of the first mounting parts, the first pin is adjacent to one of the second pins along a first direction and is adjacent to the other one of the second pins along a second direction;
and/or, in each of the second mounting parts, the second pin is adjacent to one of the first pins along the first direction and is adjacent to the other one of the first pins along the second direction; and
herein, each of the first pins is spaced apart from adjacent ones of the second pins in a same one of the mounting parts.

According to an embodiment of the present disclosure, the power terminal includes a first positive port and a first negative port disposed on the substrate; and
herein, the plurality of first pins include first positive pins each connected with the first positive port through one of the power supply traces and first negative pins each connected with the first negative port through one of the power supply traces; and the plurality of second pins include second negative pins each adjacent to one of the first positive pins along the first direction or the second direction and second positive pins each adjacent to one of the first negative pins along the first direction or the second direction.

According to an embodiment of the present disclosure, the backlight module further includes one or more first circuits connected with the first positive port and the first negative port, and each of the first circuits includes two mounting parts of the mounting parts arranged along the first direction;
herein, a first one of the two mounting parts includes one first positive pin of the first positive pins connected with the first positive port through one of the power supply traces, one second negative pin of the second negative pins disposed on a side of the first positive pin adjacent to another one of the two mounting parts along the first direction, and another second negative pin of the second negative pins adjacent to the first positive pin along the second direction; and
a second one of the two mounting parts includes one first negative pin of the first negative pins connected with the first negative port through one of the power supply traces, one second positive pin of the second positive pins disposed on a side of the first negative pin adjacent to another one of the two mounting parts along the first direction, and another second positive pin of the second positive pins adjacent to the first negative pin along the second direction.

According to an embodiment of the present disclosure, the backlight module further includes one or more second circuits connected with the first positive port and the first negative port, and each of the second circuits includes two mounting parts of the mounting parts arranged along the first direction;
herein, a first one of the two mounting parts includes one first positive pin of the first positive pins connected with the first positive port through one of the power supply traces, one second negative pin of the second negative pins disposed on a side of the first positive pin adjacent to another one of the two mounting parts along the first direction, and another first positive pin of the first positive pins adjacent to the second negative pin along the second direction; and
a second one of the two mounting parts includes one first negative pin of the first negative pins connected with the first negative port through one of the power supply traces, one second positive pin of the second positive pins disposed on a side of the first negative pin adjacent to another one of the two mounting parts along the first direction, and another first negative pin of the first negative pins adjacent to the second positive pin along the second direction.

According to an embodiment of the present disclosure, the power terminal further includes a second positive port and a second negative port, and each of the second circuits is further connected with the second positive port and the second negative port; and
herein, in each of the second circuits, the first positive pin adjacent to the second negative pin along the second direction is connected with the second positive port through one of the power supply traces, and the first negative pin adjacent to the second positive pin along the second direction is connected with the second negative port through one of the power supply traces.

According to an embodiment of the present disclosure, for one light-emitting element of the light-emitting elements and one mounting part of the mounting parts connected with each other, the light-emitting element is connected with one first positive pin of the first positive pins and one of the second negative pins adjacent to the first positive pin along the first direction or the second direction;
and/or, the light-emitting element is connected with one second positive pin of the second positive pins and one of the first negative pins adjacent to the second positive pin along the first direction or the second direction.

### Beneficial Effects

Compared with the related art, the first pins and the second pins are provided in the mounting parts of the present disclosure, and the first pin is adjacent to at least two second pins, and/or, the second pin is adjacent to at least two first pins. When the light-emitting element is connected with the mounting part, the light-emitting element may be connected with the first mounting part by being connected with the first pin and being optionally connected with one of the second pins adjacent to the first pin; and the light-emitting element may also be connected with the second mounting part by being connected with the second pin and being optionally connected with one of the first pins adjacent to the second pin. In this way, each of the light-emitting elements can be optionally arranged with different connection modes, so that the light-emitting elements of the backlight module can be each optionally arranged in different arrangement modes, thereby meeting different design requirements of the backlight module and improving compatibility and applicability of the backlight module.

### DESCRIPTION OF DRAWINGS

The technical solutions and other beneficial effects of the present disclosure will be made clear by detailed illustration of specific embodiments of the present disclosure with reference to the accompanying drawings.

FIG. 1 is a schematic diagram of a circuit structure of a backlight module in the related art;

FIG. 2 is a schematic structural view showing mounting of light-emitting elements of a backlight module according to an embodiment of the present disclosure;

FIG. 3 is a schematic structural view showing connecting of a light-emitting element according to an embodiment of the present disclosure;

FIG. 4 is a schematic diagram of a circuit structure of a backlight module according to an embodiment of the present disclosure;

FIG. 5 is another schematic structural view showing mounting of light-emitting elements of a backlight module according to an embodiment of the present disclosure;

FIG. 6 is another schematic structural view showing mounting of light-emitting elements of a backlight module according to an embodiment of the present disclosure;

FIG. 7 is another schematic structural view showing mounting of light-emitting elements of a backlight module according to an embodiment of the present disclosure;

FIG. 8 is another schematic structural view showing mounting of light-emitting elements of a backlight module according to an embodiment of the present disclosure;

FIG. 9 is a schematic diagram of another circuit structure of a backlight module according to an embodiment of the present disclosure;

FIG. 10 is a combination of luminance distribution diagrams corresponding to the backlight modules in FIG. 2 and FIG. 6 according to embodiments of the present disclosure; and

FIG. 11 is a schematic structural view of a display device according to an embodiment of the present disclosure.

### DETAILED DESCRIPTION OF EMBODIMENTS

The technical solutions in the embodiments of the present disclosure will be clearly and completely described with reference to the accompanying drawings in the embodiments of the present disclosure. Obviously, the described embodiments merely indicate a part of the embodiments of the present disclosure, but not all the embodiments. Based on the embodiments in the present disclosure, all other embodiments obtained by those skilled in the art without creative work fall into the protection scope of the present disclosure.

A number of different embodiments or examples are provided below for implementing different structures of the present disclosure. In order to simplify the disclosure, parts and arrangements of specific examples are described below. Of course, they are only examples and are not intended to restrict the present disclosure. In addition, the present disclosure may repeat reference numbers and/or reference letters in different examples for the purpose of simplicity and clarity and by itself does not indicate the relationships between the various embodiments and/or arrangements discussed. Additionally, examples of various specific processes and those skilled in the art materials are provided in the present disclosure, but those skilled in the art may be aware of other processes and/or the use of other materials.

Referring to FIG. 1, a backlight module in related art includes a plurality of positive power ports 1 and a plurality of negative power ports 2. One positive power port 1 and one negative power port 2 are grouped, and there is two circuit lines connecting therebetween. Each of the circuit lines is provided with two pads thereon, and each of the pads is provided with a positive pin 3 and a negative pin 4 thereon. At the same time, each of the pads is bonded with an LED chip 5. A positive electrode of the LED chip 5 is connected to the positive pin 3, and a negative electrode of the LED chip 5 is connected to the negative pin 4. In this way, there are four LED chips mounted between a group of the positive power port 1 and the negative power port 2. However, since an arrangement (such as arrangement directions of the pads, etc.) of the pads of the backlight module has been determined during an installation of the LED chips 5, a new circuit of the backlight module is necessary to be prepared when a new arrangement of the LED chips 5 is needed, which leads to extension of the process and increases the costs.

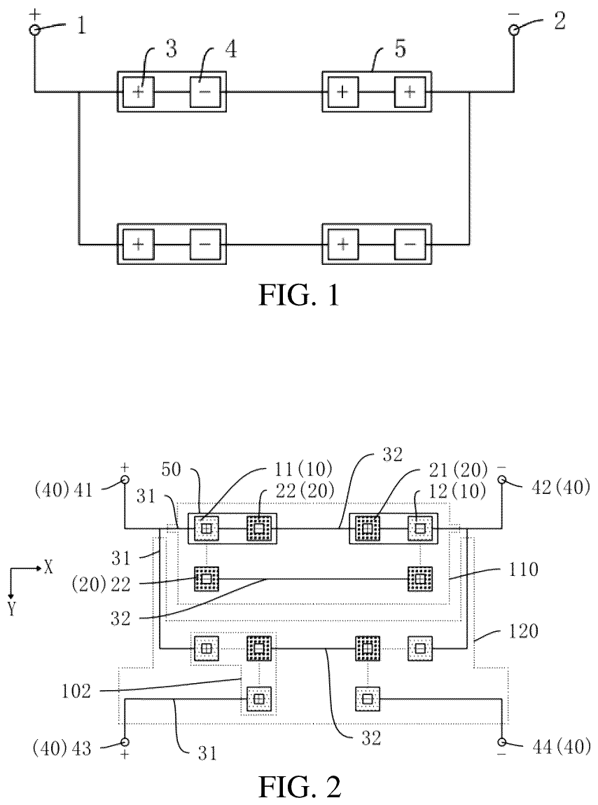

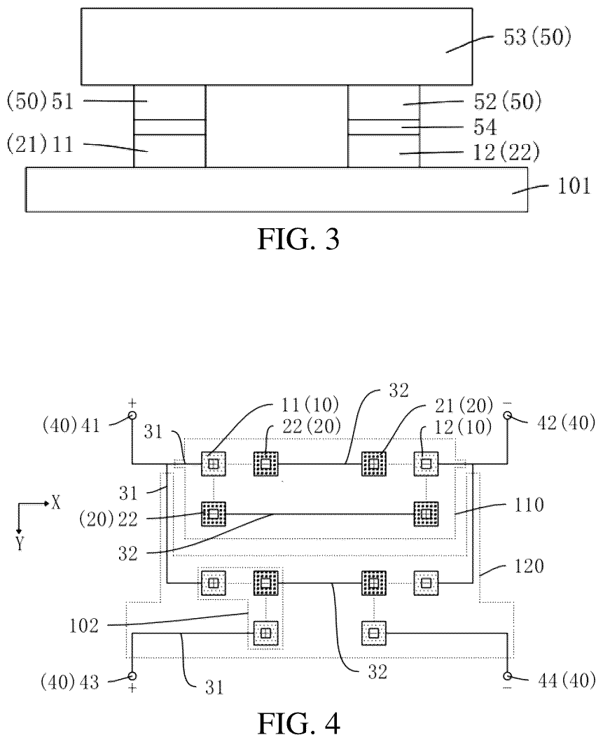

Referring to FIG. 2 and FIG. 3, a backlight module according to an embodiment of the present disclosure is provided. The backlight module includes a substrate 101, a power terminal 40, power supply traces 31, connection traces 32, and mounting parts 102.

Herein, the power terminal 40 and the power supply traces 31 are disposed on the substrate 101, and each of the power supply traces 31 is directly connected to the power terminal 40. The connection traces 32 are disposed on the substrate 101, and each of the connection traces 32 is non-directly connected with the power terminal 40. The mounting parts 102 are disposed on substrate 101 and include first pins 10 and second pins 20. Each of the first pins 10 is directly connected with one of the power supply traces 31, and each of the second pins 20 is directly connected with one of the connection traces 32. The mounting parts 102 includes first mounting parts and/or second mounting parts. Each of the first mounting parts includes one first pin 10 and at least two second pins 20 adjacent to the first pin 10. Each of the second mounting parts includes one second pin 20 and at least two first pins 10 adjacent to the second pin 20.

When light-emitting elements 50 are connected with the mounting parts 102 in an application implementation, the light-emitting element 50 may be connected with the first mounting part by being connected with the first pin 10 and being optionally connected with one of the second pins 20 adjacent to the first pin 10; and the light-emitting element 50 may also be connected with the second mounting part by being connected with the second pin 20 and being optionally connected with one of the first pins 10 adjacent to the second pin 20. In this way, each of the light-emitting elements 50 can be optionally arranged in different connection modes, so that the light-emitting elements 50 of the backlight module can be each optionally arranged in different arrangement modes, thereby meeting different design requirements of the backlight module and improving compatibility and applicability of the backlight module.

It should be noted that, the backlight module further includes light-emitting elements 50 connected with the mounting parts 102. The light-emitting elements 50 include first light-emitting elements and/or second light-emitting elements. Each of the first light-emitting elements is connected with one of the first mounting parts by being connected with the first pin 10 and one of the second pins 20 adjacent to the first pin 10. Each of the second light-emitting elements is connected with one of the second mounting parts by being connected with the second pin 20 and one of the first pins 10 adjacent to the second pin 20.

Specifically, referring to FIG. 2, FIG. 3, and FIG. 4, the backlight module includes a plurality of mounting parts 102 disposed on the substrate 101 and at least one light-emitting element 50 connected with at least a part of the mounting parts 102.

According to the embodiment of the present disclosure, the mounting part 102 includes one or more first pins 10 and one or more second pins 20. The first pins 10 and the second pins 20 of each mounting part 102 are arranged in at least one of the following two modes.

In a first mode, for the mounting part 102, one first pin 10 is adjacent to one second pin 20 along a first direction X and is adjacent to another second pin 20 along a second direction Y, and the first direction X is different from the second direction Y.

In a second mode, for the mounting part 102, one second pin 20 is adjacent to one first pin 10 along the first direction X and is adjacent to another second pin 20 along the second direction Y.

According to an embodiment, the first direction X is perpendicular to the second direction Y.

It should be noted that, in a same mounting part 102, the first pin 10 and the second pin 20 adjacent to each other are spaced apart from each other, that is, a circuit line therebetween is disconnected. When the light-emitting element 50 is connected with the mounting part 102, the first pin 10 and the second pin 20 connected with the light-emitting element 50 have the circuit line therebetween connected through the light-emitting element 50.

Conveniently, in a same first mounting part 102, a first distance is defined between the first pin 10 and any adjacent one of the at least two second pins 20; in a same second mounting part 102, a second distance is defined between the second pin 20 and any adjacent one of the at least two first pins 10; and the first distance is equal to the second distance.

In addition, the light-emitting element 50 includes a light-emitting body 53, a positive electrode 51, and a negative electrode 52. The positive electrode 51 and the negative electrode 52 are disposed on a side of the light-emitting body 53 adjacent to the mounting part 102. A distance between the positive electrode 51 and the negative electrode 52 is equal to the first distance or the second distance, so that each of the light-emitting elements 50 having a same size can be connected to the mounting part 102 by any pair of adjacent first pin 10 and second pin 20 of the mounting part 102.

Furthermore, the power terminal 40 includes a first positive port 41 and a first negative port 42 disposed on the substrate 101. Herein, the first pins 10 include first positive pins 11 each connected with the first positive port 41 through one of the power supply traces 31 and first negative pins 12 each connected with the first negative port 42 through one of the power supply traces 31; and the second pins 20 include second negative pins 22 each adjacent to one of the first positive pins 11 along the first direction X or the second direction Y and second positive pins 21 each adjacent to one of the first negative pins 12 along the first direction X or the second direction Y.

Each mounting part 102 correspondingly includes a positive pin (such as the first positive pin 11 or the second positive pin 21) and a negative pin (such as the first negative pin 12 or the second negative pin 22). In this way, for the light-emitting element 50 and the mounting part 102 connected with each other, the positive electrode 51 of the light-emitting element 50 can be connected with the positive pin through a conductive material 54, and the negative electrode 52 of the light-emitting element 50 can be connected with the negative pin through the conductive material 54, as shown in FIG. 3.

It can be understood that, since the mounting parts 102 have the first pins 10 and the second pins 20 with different numbers and arrangements, different connection modes may be provided between the light-emitting element 50 and the mounting part 102, so that each of the light-emitting elements 50 can be optionally arranged in different arrangement modes. Details refer to the following specific embodiments.

According to an embodiment of the present disclosure, referring to FIG. 2, FIG. 3, and FIG. 4, the backlight module in the embodiment further includes one or more first circuits 110 connected to the first positive port 41 and the first negative port 42. Herein, each of the first circuits 110 includes two mounting parts 102 arranged along the first direction X. One of the two mounting parts 102 is connected with the first positive port 41 through one of the power supply traces 31, the other one of the two mounting parts 102 is connected with the first negative port 42 through another one of the power supply traces 31, and the two mounting parts 102 are connected with each other through one of the connection traces 32.

For the mounting part 102 in the first circuit 110 connected with the first positive port 41, the mounting part 102 includes one first positive pin 11 connected with the first positive port 41 through one of the power supply traces 31, a second negative pin 22 disposed on a side of the first positive pin 11 adjacent to the other mounting part 102 along the first direction X, and another second negative pin 22 adjacent to the first positive pin 11 along the second direction Y.

For the mounting part 102 in the first circuit 110 connected with the first negative port 42, the mounting part 102 includes one first negative pin 12 connected with the first negative port 42 through one of the power supply traces 31, one second positive pin 21 disposed on a side of the first negative pin 12 adjacent to the other mounting part 102 along the first direction X, and another second positive pin 21 adjacent to the first negative pin 12 along the second direction Y.

For the two mounting parts 102 in the first circuit 110, the second negative pin 22 in one of the mounting parts 102 is connected with the second positive pin 21 in the other one of the mounting parts 102 through one of the connection traces 32. Specifically, the two second negative pins 22 are correspondingly connected with the two second positive pins 21 through the connection traces 32, respectively.

In addition, the backlight module further includes a second circuit 120 connected with the first positive port 41 and the first negative port 42, and the second circuit 120 includes two mounting parts 102 arranged along the first direction X. One of the two mounting parts 102 is connected with the first positive port 41 through one of the power supply traces 31, and the other one of the two mounting parts 102 is connected with the first negative port 42 through another one of the power supply traces 31.

For the mounting part 102 in the second circuit 120 connected with the first positive port 41, the mounting part 102 includes one first positive pin 11 connected with the first positive port 41 through one of the power supply traces 31, one second negative pin 22 disposed on a side of the first positive pin 11 adjacent to the other mounting part 102 along the first direction X, and another first positive pin 11 adjacent to the second negative pin 22 along the second direction Y.

For the mounting part 102 in the second circuit 120 connected with the first negative port 42, the mounting part 102 includes one first negative pin 12 connected with the first negative port 42 through one of the power supply traces 31, one second positive pin 21 disposed on a side of the first negative pin 12 adjacent to the other mounting part 102 along the first direction X, and another first negative pin 12 adjacent to the second positive pin 21 along the second direction Y.

For the two mounting parts 102 in the second circuit 120, the second negative pin 22 in one of the mounting parts 102 is connected with the second positive pin 21 in the other mounting part 102 through one of the connection traces 32.

In addition, according to the embodiment of the present, the power terminal 40 further includes a second positive port 43 and a second negative port 44. The second circuit 120 is further connected with the second positive port 43 and the second negative port 44. For the two mounting parts 102 in the second circuit 120, the first positive pin 11 adjacent to the second negative pin 22 along the second direction Y is connected with the second positive port 43 through one of the power supply traces 31, and the first negative pin 12 adjacent to the second positive pin 21 along the second direction Y is connected with the second negative port 44 through another one of the power supply traces 31.

The light-emitting element 50 can be connected with any one of the mounting parts 102 in the first circuit 110 and the second circuit 120, thereby forming at least one of the following two connection modes.

In a first mode, for the light-emitting element 50 and the mounting part 102 connected with each other, the light-emitting element 50 is connected with one first positive pin 11 and one second negative pin 22 adjacent to the first positive pin 11 along the first direction X or the second direction Y.

In a second mode, for the light-emitting element 50 and the mounting part 102 connected with each other, the light-emitting element 50 is connected with one second positive pin 21 and one first negative pin 12 adjacent to the second positive pin 21 along the first direction X or the second direction Y.

According to the embodiments of the present disclosure, as shown in FIG. 4, the first positive port 41, the first negative port 42, the second positive port 43, the second negative port 44, the first circuit 110, the second circuit 120, and at least one light-emitting elements 50 mounted in the first circuit 110 and/or the second circuit 120 form a light-emitting group.

It should be noted that, the backlight module may include a plurality of light-emitting groups, and the mounting parts 102 in various connection modes are provide in each light-emitting group, so that the light-emitting elements 50 with various arrangement modes can be provided in the light-emitting group, thereby improving compatibility and applicability of the backlight module.

Referring to FIG. 2, each light-emitting group according to the embodiment may have two light-emitting elements 50, and the two light-emitting elements 50 are mounted in the first circuit 110 and respectively connected with the two mounting parts 102 in the first circuit 110.

Herein, one of the light-emitting elements 50 is connected with the mounting part 102 which is connected with the first positive port 41 through one of the power supply traces 31. Specifically, the light-emitting element 50 is connected with the first positive pin 11 and the second negative pin 22 adjacent to the first positive pin 11 along the first direction X. The other one of the light-emitting elements 50 is connected with the mounting part 102 which is connected with the first negative port 42 through another one of the power supply traces 31. Specifically, the light-emitting element 50 is connected with the first negative pin 12 and the second positive pin 21 adjacent to the first negative pin 12 along the first direction X.

In view of above, each light-emitting group according to the embodiment of the present disclosure can be provided with two light-emitting elements 50, and the two light-emitting elements 50 can be each arranged along the first direction X.

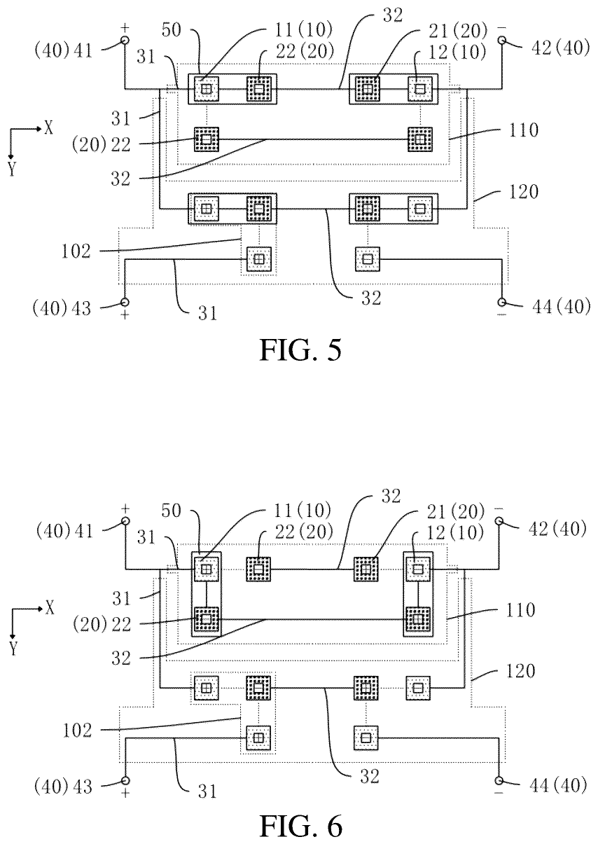

According to another embodiment of the present disclosure, referring to FIG. 5, the embodiment differs from the first embodiment in that: each light-emitting group is provided with four light-emitting elements 50.

Specifically, two light-emitting elements 50 are mounted in the first circuit 110, and the other two light-emitting elements 50 are mounted in second circuit 120.

In the first circuit 110, one of the light-emitting elements 50 is connected with the mounting part 102 which is connected with the first positive port 41 through one of the power supply traces 31. Specifically, the light-emitting element 50 is connected with the first positive pin 11 and the second negative pin 22 adjacent to the first positive pin 11 along the first direction X. The other one of the light-emitting elements 50 is connected with the mounting part 102 which is connected with the first negative port 42 through another one of the power supply traces 31. Specifically, the light-emitting element 50 is connected with the first negative pin 12 and the second positive pin 21 adjacent to the first negative pin 12 along the first direction X.

In second circuit 120, one of the light-emitting elements 50 is connected with the mounting part 102 which is connected with the first positive port 41 through one of the power supply traces 31. Specifically, the light-emitting element 50 is connected with the second negative pin 22 and the first positive pin 11 adjacent to the second negative pin 22 along the first direction X. The other one of the light-emitting elements 50 is connected with the mounting part 102 which is connected with the first negative port 42 through another one of the power supply traces 31. Specifically, the light-emitting element 50 is connected with the second positive pin 21 and the first negative pin 12 adjacent to the second positive pin 21 along the first direction X.

In view of above, each light-emitting group according to the embodiment of the present disclosure can be provided with four light-emitting elements 50, and the four light-emitting elements 50 can be each arranged along the first direction X.

According to another embodiment of the present disclosure, referring to FIG. 6, the embodiment differs from the first embodiment in that: each light-emitting group is provided with two light-emitting elements 50, and the two light-emitting elements 50 are mounted in the first circuit 110.

In the first circuit 110, one of the light-emitting elements 50 is connected with the mounting part 102 which is connected with the first positive port 41 through one of the power supply traces 31. Specifically, the light-emitting element 50 is connected with the first positive pin 11 and the second negative pin 22 adjacent to the first positive pin 11 along the second direction Y. The other one of the light-emitting elements 50 is connected with the mounting part 102 which is connected with the first negative port 42 through another one of the power supply traces 31. Specifically, the light-emitting element 50 is connected with the first negative pin 12 and the second positive pin 21 adjacent to the first negative pin 12 along the second direction Y.

In view of above, each light-emitting group according to the embodiment of the present disclosure can be provided with two light-emitting elements 50, and the two light-emitting elements 50 can be each arranged along the second direction Y.

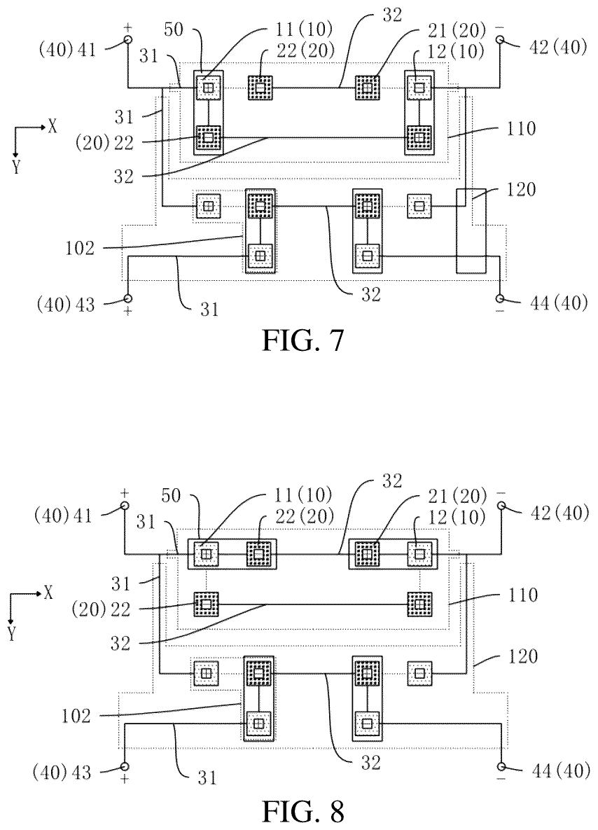

According to another embodiment of the present disclosure, referring to FIG. 7, the embodiment differs from the embodiment shown in FIG. 6 in that: each light-emitting group is provided with four light-emitting elements 50, two light-emitting elements 50 are mounted in the first circuit 110, and the other two light-emitting elements 50 are mounted in second circuit 120.

In the first circuit 110, one of the light-emitting elements 50 is connected with the mounting part 102 which is connected with the first positive port 41 through one of the power supply traces 31. Specifically, the light-emitting element 50 is connected with the first positive pin 11 and the second negative pin 22 adjacent to the first positive pin 11 along the second direction Y. The other one of the light-emitting elements 50 is connected with the mounting part 102 which is connected with the first negative port 42 through another one of the power supply traces 31. Specifically, the light-emitting element 50 is connected with the first negative pin 12 and the second positive pin 21 adjacent to the first negative pin 12 along the second direction Y.

In the second circuit 120, one of the light-emitting elements 50 is connected with the mounting part 102 which is connected with the first positive port 41 through one of the power supply traces 31. Specifically, the light-emitting element 50 is connected with the second negative pin 22 and the first positive pin 11 adjacent to the second negative pin 22 along the second direction Y. The other one of the light-emitting elements 50 is connected with the mounting part 102 which is connected with the first negative port 42 through another one of the power supply traces 31. Specifically, the light-emitting element 50 is connected with the second positive pin 21 and the first negative pin 12 adjacent to the second positive pin 21 along the second direction Y.

In view of above, each light-emitting group according to the embodiment of the present disclosure can be provided with four light-emitting elements 50, and the four light-emitting elements 50 can be each arranged along the second direction Y.

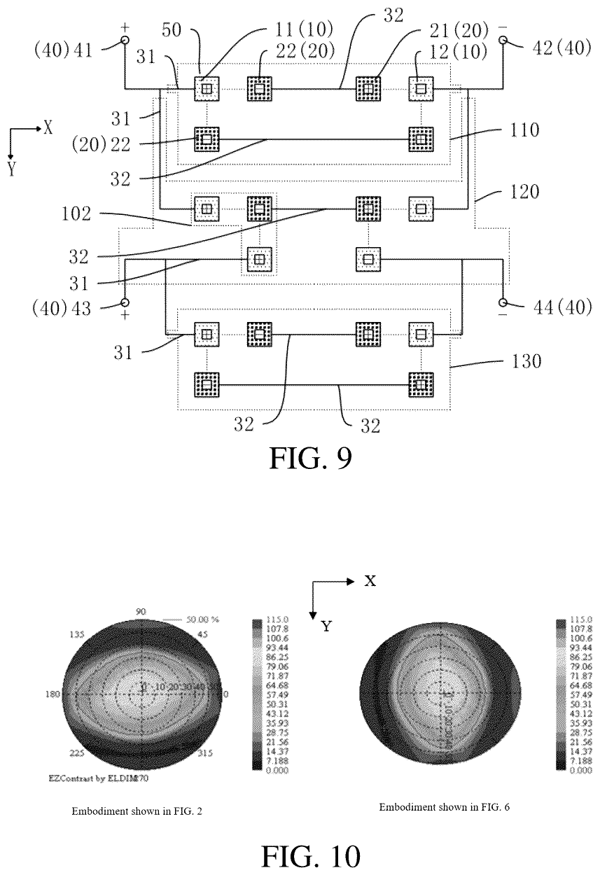

According to another embodiment of the present disclosure, referring to FIG. 8, each light-emitting group according to the embodiment is provided with four light-emitting elements 50, two light-emitting elements 50 are mounted in the first circuit 110, and the other two light-emitting elements 50 are mounted in second circuit 120.

In the first circuit 110, one of the light-emitting elements 50 is connected with the mounting part 102 which is connected with the first positive port 41 through one of the power supply traces 31. Specifically, the light-emitting element 50 is connected with the first positive pin 11 and the second negative pin 22 adjacent to the first positive pin 11 along the first direction X. The other one of the light-emitting elements 50 is connected with the mounting part 102 which is connected with the first negative port 42 through another one of the power supply traces 31. Specifically, the light-emitting element 50 is connected with the first negative pin 12 and the second positive pin 21 adjacent to the first negative pin 12 along the first direction X.

In the second circuit 120, one of the light-emitting elements 50 is connected with the mounting part 102 which is connected with the first positive port 41 through one of the power supply traces 31. Specifically, the light-emitting element 50 is connected with the second negative pin 22 and the first positive pin 11 adjacent to the second negative pin 22 along the second direction Y. The other one of the light-emitting elements 50 is connected with the mounting part 102 which is connected with the first negative port 42 through another one of the power supply traces 31. Specifically, the light-emitting element 50 is connected with the second positive pin 21 and the first negative pin 12 adjacent to the second positive pin 21 along the second direction Y.

In view of above, each light-emitting group according to the embodiment of the present disclosure can be provided with four light-emitting elements 50, two light-emitting elements 50 can be each arranged along the first direction X, and the other two light-emitting elements 50 can be each arranged along the second direction Y.

In can be understood that, according to other embodiments of the present disclosure, each light-emitting group may include four light-emitting elements 50, two light-emitting elements 50 can be mounted in the first circuit 110 and each arranged along the second direction Y, and the other two light-emitting elements 50 can be mounted in the second circuit 120 and each arranged along the first direction X. The connection mode between the light-emitting element 50 and the mounting part 102 refers to that of the preceding embodiments, which is not repeated here.

According to another embodiment of the present disclosure, referring to FIG. 9, the embodiment differs from the embodiment shown in FIG. 4 in that: the backlight module further includes a third circuit 130 connected with the second positive port 43 and the second negative port 44.

Herein, the third circuit 130 includes two mounting parts 102 arranged along the first direction X. One of the mounting parts 102 is connected with the second positive port 43 through one of the power supply traces 31, and the other one of the mounting parts 102 is connected with the second negative port 44 through another one of the power supply traces 31. The two mounting parts 102 are connected with each other through one of the connection traces 32.

For the mounting part 102 in the third circuit 130 connected with the second positive port 43, the mounting part 102 includes one first positive pin 11 connected with the second positive port 43 through one of the power supply traces 31, one second negative pin 22 disposed on a side of the first positive pin 11 adjacent to the other mounting part 102 along the first direction X, and another one second negative pin 22 adjacent to the first positive pin 11 along the second direction Y.

For the mounting part 102 in the third circuit 130 connected with the second negative port 44, the mounting part 102 includes one first negative pin 12 connected with the second negative port 44 through one of the power supply traces 31, one second positive pin 21 disposed on a side of the first negative pin 12 adjacent to the other mounting part 102 along the first direction X, and another second positive pin 21 adjacent to the first negative pin 12 along the second direction Y.

For the two mounting parts 102 in the third circuit 130, the second negative pin 22 of one of the mounting parts 102 is connected with the second positive pin 21 of the other mounting part 102 through one of the connection traces 32. Specifically, the two second negative pins 22 are correspondingly connected with the two second positive pins 21 through the connection traces 32, respectively.

According to the embodiment shown in FIG. 9, each light-emitting group includes six mounting parts 102, and there are six light-emitting elements 50 can be mounted thereon at most. The six light-emitting elements 50 can be each independently arranged along the first direction X or the second direction Y. Specific connection modes refer to those in preceding embodiments, which are not repeated here.

It should be noted that, according to other embodiments of the present disclosure, circuits of the light-emitting group may be added, that is, a fourth circuit, a fifth circuit, and so on can be added. Correspondingly, ports of the power terminal 40 can be added. In this way, the light-emitting elements 50 of single light-emitting group can be more. Specific parameters can be selected according to actual demand and are not limited here.

Referring to FIG. 2, FIG. 6, and FIG. 10, herein, FIG. 10 is a combination of luminance distribution diagrams corresponding to the two backlight modules shown in FIG. 2 and FIG. 6. As shown in FIG. 10, when the light-emitting element 50 is arranged along the first direction X, luminance of the backlight module is distributed along the first direction X. When the light-emitting element 50 is arranged along the second direction Y, luminance of the backlight module is distributed along the second direction Y. In this way, arrangement of the light-emitting elements 50 can be selected according to the actual luminance demand.

In summary, according to the embodiments of the present disclosure, when connected with the mounting part 102, the light-emitting element 50 can be connected with the first pin 10 and optionally connected with one of the second pins 20 adjacent to the first pin 10, the light-emitting element 50 can also be connected with the second pin 20 and optionally connected with one of the first pins 10 adjacent to the second pin 20. In this way, each of the light-emitting elements 50 can be optionally arranged in different mounting modes, so that the light-emitting elements 50 of the backlight module can be each optionally arranged in different arrangement modes, thereby meeting different design requirements of the backlight module and improving compatibility and applicability of the backlight module.

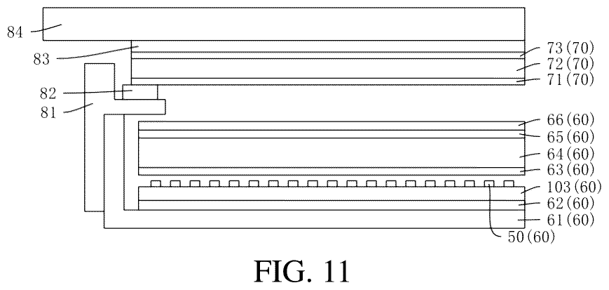

In addition, referring to FIG. 11, a display device according to an embodiment of the present disclosure is provided. The display device includes a display panel 70 and the backlight module 60 in the preceding embodiments, and the display panel 70 is disposed on a light output side of the backlight module 60.

Specifically, the backlight module 60 includes a frame 61, a heat-conducting glue 62 disposed in the frame 61, a circuit board 103 disposed on the heat-conducting glue 62, the light-emitting elements 50 disposed on the circuit board 103, a fluorescent sheet 63 disposed on a side of the light-emitting elements 50 away from the circuit board 103, a light guide plate 64 disposed on the fluorescent sheet 63, a brightness enhancement film 65 disposed on the light guide plate 64, and a prismatic lens 66 disposed on the brightness enhancement film 65.

The display device further includes a middle frame 81 disposed on the backlight module 60, and the display panel 70 is disposed on the middle frame 81. The middle frame 81 acts to support and fix the backlight module 60 and display panel 70.

The display panel 70 includes a lower polaroid 71, a panel body 72 disposed on a side of the lower polaroid 71 away from the backlight module 60, and an upper polaroid 73 disposed on a side of the panel body 72 away from the lower polaroid 71.

The display device further includes a foam layer 82 between the display panel 70 and the middle frame 81 to buffer the stress.

In addition, the display device further includes a cover plate 84 disposed on a side of the display panel 70 away from the backlight module 60 and an adhesive layer 83 connected between the display panel 70 and the cover plate 84.

According to the embodiment of the present disclosure, the circuit board 103 includes the substrate 101 mentioned in above embodiments and members disposed on the substrate 101 such as the mounting parts 102, the power terminal 40, the power supply traces 31, the connection traces 32, and so on. Specific arrangement modes and connection modes refer to the preceding embodiments, which are not repeated here.

In the above embodiments, the description of each embodiment has its own emphasis. For the part not detailed in one embodiment, please refer to the relevant description of other embodiments.

The backlight modules and display devices provided according to embodiments of the present disclosure have been described above in detail. Specific examples are used to illustrate the principle and implementations of the present disclosure. The illustration of the above embodiments is intended only to assist in understanding the technical solutions and core ideas of the present disclosure. It should be understood that, those skilled in the art can modify the technical solutions according to the preceding embodiments or make equivalent substitution of some of the technical features. Such modification or substitution shall not remove the essence of the corresponding technical solutions from the scope of the technical solutions according to embodiments of the present disclosure.

1. A backlight module, comprising:
a substrate;
a power terminal and a plurality of power supply traces, disposed on the substrate, wherein each of the power supply traces is directly connected with the power terminal;
a plurality of connection traces, disposed on the substrate, wherein each of the connection traces is non-directly connected with the power terminal; and
a plurality of mounting parts, disposed on the substrate, the plurality of mounting parts comprising a plurality of first pins and a plurality of second pins, each of the first pins being directly connected with one of the power supply traces, and each of the second pins being directly connected with one of the connection traces, wherein the plurality of mounting parts comprise first mounting parts, each of which comprising one first pin of the first pins and at least two second pins of the second pins adjacent to the first pin, and/or, second mounting parts, each of which comprising one second pin of the second pins and at least two first pins of the first pins adjacent to the second pin.

2. The backlight module according to claim 1, wherein the backlight module further comprises light-emitting elements each connected with one of the mounting parts; and the light-emitting elements comprise first light-emitting elements, each of which connected with the first pin and an adjacent one of the second pins in a same one of the first mounting parts, and/or, second light-emitting element, each of which connected with the second pin and an adjacent one of the first pins in a same one of the second mounting parts.

3. The backlight module according to claim 2, wherein in each of the first mounting parts, the first pin is adjacent to one of the second pins along a first direction and is adjacent to the other one of the second pins along a second direction; and/or, in each of the second mounting parts, the second pin is adjacent to one of the first pins along the first direction and is adjacent to the other one of the first pins along the second direction; and
wherein each of the first pins is spaced apart from adjacent ones of the second pins in a same one of the mounting parts.

4. The backlight module according to claim 3, wherein the power terminal comprises a first positive port and a first negative port disposed on the substrate; and
wherein the plurality of first pins comprise first positive pins each connected with the first positive port through one of the power supply traces and first negative pins each connected with the first negative port through one of the power supply traces; and the plurality of second pins comprise second negative pins each adjacent to one of the first positive pins along the first direction or the second direction and second positive pins each adjacent to one of the first negative pins along the first direction or the second direction.

5. The backlight module according to claim 4, wherein the backlight module further comprises one or more first circuits connected with the first positive port and the first negative port, and each of the first circuits comprises two mounting parts of the mounting parts arranged along the first direction;
wherein a first one of the two mounting parts comprises one first positive pin of the first positive pins connected with the first positive port through one of the power supply traces, one second negative pin of the second negative pins disposed on a side of the first positive pin adjacent to another one of the two mounting parts along the first direction, and another second negative pin of the second negative pins adjacent to the first positive pin along the second direction; and
wherein a second one of the two mounting parts comprises one first negative pin of the first negative pins connected with the first negative port through one of the power supply traces, one second positive pin of the second positive pins disposed on a side of the first negative pin adjacent to another one of the two mounting parts along the first direction, and another second positive pin of the second positive pins adjacent to the first negative pin along the second direction.

6. The backlight module according to claim 5, wherein in each of the first circuits, the second negative pins in the first one of the two mounting parts are each connected with one of the second positive pins in the second one of the two mounting parts through one of the connection trances.

7. The backlight module according to claim 4, wherein the backlight module further comprises one or more second circuits connected with the first positive port and the first negative port, and each of the second circuits comprises two mounting parts of the mounting parts arranged along the first direction;
wherein a first one of the two mounting parts comprises one first positive pin of the first positive pins connected with the first positive port through one of the power supply traces, one second negative pin of the second negative pins disposed on a side of the first positive pin adjacent to another one of the two mounting parts along the first direction, and another first positive pin of the first positive pins adjacent to the second negative pin along the second direction; and
wherein a second one of the two mounting parts comprises one first negative pin of the first negative pins connected with the first negative port through one of the power supply traces, one second positive pin of the second positive pins disposed on a side of the first negative pin adjacent to another one of the two mounting parts along the first direction, and another first negative pin of the first negative pins adjacent to the second positive pin along the second direction.

8. The backlight module according to claim 7, wherein in each of the second circuits, the second negative pin in the first one of the two mounting parts is connected with the second positive pin in the second one of the two mounting parts through one of the connection trances.

9. The backlight module according to claim 7, wherein the power terminal further comprises a second positive port and a second negative port, and each of the second circuits is further connected with the second positive port and the second negative port; and
wherein in each of the second circuits, the first positive pin adjacent to the second negative pin along the second direction is connected with the second positive port through one of the power supply traces, and the first negative pin adjacent to the second positive pin along the second direction is connected with the second negative port through one of the power supply traces.

10. The backlight module according to claim 4, wherein for one light-emitting element of the light-emitting elements and one mounting part of the mounting parts connected with each other,
the light-emitting element is connected with one first positive pin of the first positive pins and one of the second negative pins adjacent to the first positive pin along the first direction or the second direction; or
the light-emitting element is connected with one second positive pin of the second positive pins and one of the first negative pins adjacent to the second positive pin along the first direction or the second direction.

11. The backlight module according to claim 2, wherein in each of the first mounting parts, a first distance is defined between the first pin and any one of the at least two second pins adjacent to the first pin;
in each of the second mounting parts, a second distance is defined between the second pin and any one of the at least two first pins adjacent to the second pin; and
the first distance is equal to the second distance.

12. The backlight module according to claim 11, wherein each of the light-emitting elements comprises a positive electrode and a negative electrode; and for one light-emitting element of the light-emitting elements and one mounting part of the mounting parts connected with each other, the positive electrode is connected with one of the first pin and the second pin, and the negative electrode is connected with the other one of the first pin and the second pin; and
wherein a distance between the positive electrode and the negative electrode is equal to the first distance or the second distance.

13. A display device, comprising a display panel and a backlight module, the display panel disposed on a light output side of the backlight module, and the backlight module comprising:
a substrate;
a power terminal and a plurality of power supply traces, disposed on the substrate, wherein each of the power supply traces is directly connected with the power terminal;
a plurality of connection traces, disposed on the substrate, wherein each of the connection traces is non-directly connected with the power terminal; and
a plurality of mounting parts, disposed on the substrate, the plurality of mounting parts comprising a plurality of first pins and a plurality of second pins, each of the first pins being directly connected with one of the power supply traces, and each of the second pins being directly connected with one of the connection traces, wherein the plurality of mounting parts comprise first mounting parts, each of which comprising one first pin of the first pins and at least two second pins of the second pins adjacent to the first pin, and/or, second mounting parts, each of which comprising one second pin of the second pins and at least two first pins of the first pins adjacent to the second pin.

14. The display device according to claim 13, wherein the backlight module further comprises light-emitting elements each connected with one of the mounting parts; and the light-emitting elements comprise first light-emitting elements, each of which connected with the first pin and an adjacent one of the second pins in a same one of the first mounting parts, and/or, second light-emitting element, each of which connected with the second pin and an adjacent one of the first pins in a same one of the second mounting parts.

15. The display device according to claim 14, wherein in each of the first mounting parts, the first pin is adjacent to one of the second pins along a first direction and is adjacent to the other one of the second pins along a second direction; and/or, in each of the second mounting parts, the second pin is adjacent to one of the first pins along the first direction and is adjacent to the other one of the first pins along the second direction; and
wherein each of the first pins is spaced apart from adjacent ones of the second pins in a same one of the mounting parts.

16. The display device according to claim 15, wherein the power terminal comprises a first positive port and a first negative port disposed on the substrate; and
wherein the plurality of first pins comprise first positive pins each connected with the first positive port through one of the power supply traces and first negative pins each connected with the first negative port through one of the power supply traces; and the plurality of second pins comprise second negative pins each adjacent to one of the first positive pins along the first direction or the second direction and second positive pins each adjacent to one of the first negative pins along the first direction or the second direction.

17. The display device according to claim 16, wherein the backlight module further comprises one or more first circuits connected with the first positive port and the first negative port, and each of the first circuits comprises two mounting parts of the mounting parts arranged along the first direction;
wherein a first one of the two mounting parts comprises one first positive pin of the first positive pins connected with the first positive port through one of the power supply traces, one second negative pin of the second negative pins disposed on a side of the first positive pin adjacent to another one of the two mounting parts along the first direction, and another second negative pin of the second negative pins adjacent to the first positive pin along the second direction; and
wherein a second one of the two mounting parts comprises one first negative pin of the first negative pins connected with the first negative port through one of the power supply traces, one second positive pin of the second positive pins disposed on a side of the first negative pin adjacent to another one of the two mounting parts along the first direction, and another second positive pin of the second positive pins adjacent to the first negative pin along the second direction.

18. The display device according to claim 16, wherein the backlight module further comprises one or more second circuits connected with the first positive port and the first negative port, and each of the second circuits comprises two mounting parts of the mounting parts arranged along the first direction;
wherein a first one of the two mounting parts comprises one first positive pin of the first positive pins connected with the first positive port through one of the power supply traces, one second negative pin of the second negative pins disposed on a side of the first positive pin adjacent to another one of the two mounting parts along the first direction, and another first positive pin of the first positive pins adjacent to the second negative pin along the second direction; and
wherein a second one of the two mounting parts comprises one first negative pin of the first negative pins connected with the first negative port through one of the power supply traces, one second positive pin of the second positive pins disposed on a side of the first negative pin adjacent to another one of the two mounting parts along the first direction, and another first negative pin of the first negative pins adjacent to the second positive pin along the second direction.

19. The display device according to claim 18, wherein the power terminal further comprises a second positive port and a second negative port, and each of the second circuits is further connected with the second positive port and the second negative port; and
wherein in each of the second circuits, the first positive pin adjacent to the second negative pin along the second direction is connected with the second positive port through one of the power supply traces, and the first negative pin adjacent to the second positive pin along the second direction is connected with the second negative port through one of the power supply traces.

20. The display device according to claim 16, wherein for one light-emitting element of the light-emitting elements and one mounting part of the mounting parts connected with each other,
the light-emitting element is connected with one first positive pin of the first positive pins and one of the second negative pins adjacent to the first positive pin along the first direction or the second direction; or
the light-emitting element is connected with one second positive pin of the second positive pins and one of the first negative pins adjacent to the second positive pin along the first direction or the second direction.
